(19) United States
(12) Patent Application Publication
(10) Pub. No.: US 2024/0022852 A1
(43) Pub. Date: Jan. 18, 2024

(54) Microspeaker Enclosure Including Porous Particle Material

(71) Applicant: EM-TECH Co., Ltd., Gyeongsangnam-do (KR)

(72) Inventors: Jae Hwa Lim, Gyeongsangnam-do (KR); Young Uk Jo, Gyeongsangnam-do (KR); Dong Hyun Yun, Gyeongsangnam-do (KR)

(21) Appl. No.: 18/349,290

(22) Filed: Jul. 10, 2023

(30) Foreign Application Priority Data
Jul. 12, 2022 (KR) 10-2022-0085445

(51) Int. Cl. H04R 1/28; H05K 1/18

(52) U.S. Cl. CPC H04R 1/288; H04R 1/2811; H05K 1/189; H04R 2400/11

(57) ABSTRACT

A microspeaker enclosure includes a microspeaker, an enclosure case in which the microspeaker is mounted, including a back volume communicating with the microspeaker, a block installed in the back volume and formed of a porous material serving as a virtual back volume by adsorbing air, and porous particles installed in the back volume and serving as a virtual back volume by adsorbing air.

### TECHNICAL FIELD

The present disclosure relates to a microspeaker enclosure including a porous material.

### BACKGROUND

A microspeaker is a device provided in portable devices or the like to generate sound and is installed in various devices according to the recent development of mobile devices. In particular, recently developed mobile devices tend to be lighter, smaller, and slimmer to facilitate portability, and accordingly, microspeakers installed in mobile devices are required to be smaller and slimmer.

However, when microspeakers are miniaturized or slimmed, the area of a diaphragm becomes smaller and the size of a resonance space, in which sound generated as a diaphragm vibrates resonates and is amplified, also decreases, so sound pressure decreases. This decrease in sound pressure is particularly noticeable in a low-frequency range, and in order to strengthen sound pressure in the low-frequency range, technology for placing an air adsorbent, a porous material, in the resonance space so that the porous material adsorbs air molecules to create a virtual acoustic space, thereby enhancing a sound pressure level (SPL) of the low-frequency range and reducing total harmonic distortion (THD) of the low-frequency range, has been developed.

FIG. 1 is a view illustrating a microspeaker enclosure filled with a porous material according to the related art. According to the related art, a microspeaker 1 is mounted on enclosure cases 2 and 3, and a back volume 4 is provided between the upper and lower enclosure cases 2 and 3. The back volume 4 communicates with a back hole of the microspeaker 1 and is filled with porous particless 5. As the porous particles 5 adsorb air molecules, a virtual acoustic space is formed to provide an effect as if the back volume 4 is expanded.

However, the microspeaker enclosure filled with a porous material according to the related art is disadvantageous in that noise occurs when the microspeaker 1 generates sound or the porous particles 5 vibrate due to an impact applied to the enclosure.

In order to solve these disadvantages, technologies for blocking porous particles and installing the blocked porous particles in an enclosure have been disclosed. However, in the case of blocking porous particles, air may not be circulated to particles located inside the porous particle block, and thus, as the size of the block increases, air adsorption performance gradually decreases.

### SUMMARY

An aspect of the present disclosure provides a microspeaker enclosure including both a porous block, formed by blocking porous particles, and porous particles in a back volume.

According to an aspect of the present disclosure for achieving the above objects, a microspeaker enclosure includes: a microspeaker; an enclosure case in which the microspeaker is mounted, including a back volume communicating with the microspeaker; a block installed in the back volume and formed of a porous material serving as a virtual back volume by adsorbing air; and porous particles installed in the back volume and serving as a virtual back volume by adsorbing air.

Also, in an aspect of an embodiment, a plurality of blocks formed of a porous material may be provided, and the plurality of blocks may have different thicknesses.

Also, in an aspect of an embodiment, the porous block may be attached to one surface of the enclosure case, and an interval between a counterpart, facing the porous block, and the porous block may be 0.05 mm or more.

Also, in an aspect of an embodiment, the counterpart facing the porous block may be at least one of the enclosure cases, another porous block, the microspeaker, a flexible printed circuit board (FPCB), a polyurethane such as PORON which is a microcellular (fine pitch) open cell urethane foam manufactured by Rogers Corporation, a sound absorbing material, and an electronic component mounted in the enclosure case.

Also, in an aspect of an embodiment, the porous block may have dimensions in which a width and length thereof are at least 1.5 times or more a thickness thereof.

Also, in an aspect of an embodiment, the porous material forming the porous block and the porous particles may include any one or more of zeolite, activated carbon, a metal-organic framework (MOF), an aerogel, and porous silica.

The microspeaker enclosure including a porous material provided by the present disclosure includes both the porous block and porous particles, so that the block may be installed in a location in which noise is likely to occur and a location in which noise is less likely to occur is filled with porous particles, thereby increasing air adsorption performance to improve a virtual backvolume effect.

### BRIEF DESCRIPTION OF THE DRAWINGS

FIG. 1 illustrates the microspeaker enclosure filled with a porous material according to the related art;

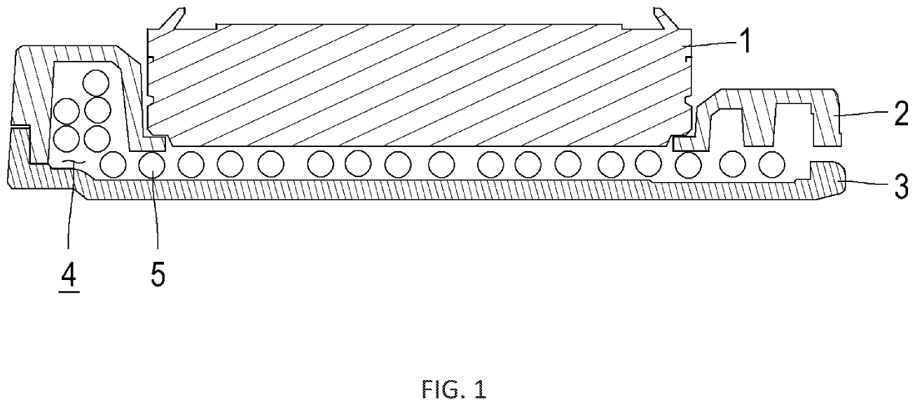

FIG. 2 is a plan view of a microspeaker enclosure including a porous material according to one embodiment of the present disclosure;

FIG. 3 is a perspective view of a microspeaker enclosure including a porous material according to one embodiment of the present disclosure;

FIG. 4 is a cross-sectional view illustrating a block formed of a porous material according to one embodiment of the present disclosure; and

FIG. 5 is a cross-sectional view schematically illustrating a size ratio of a block formed of a porous material according to one embodiment of the present disclosure.

### DETAILED DESCRIPTION

Hereinafter, embodiments are described in detail with reference to the accompanying drawings.

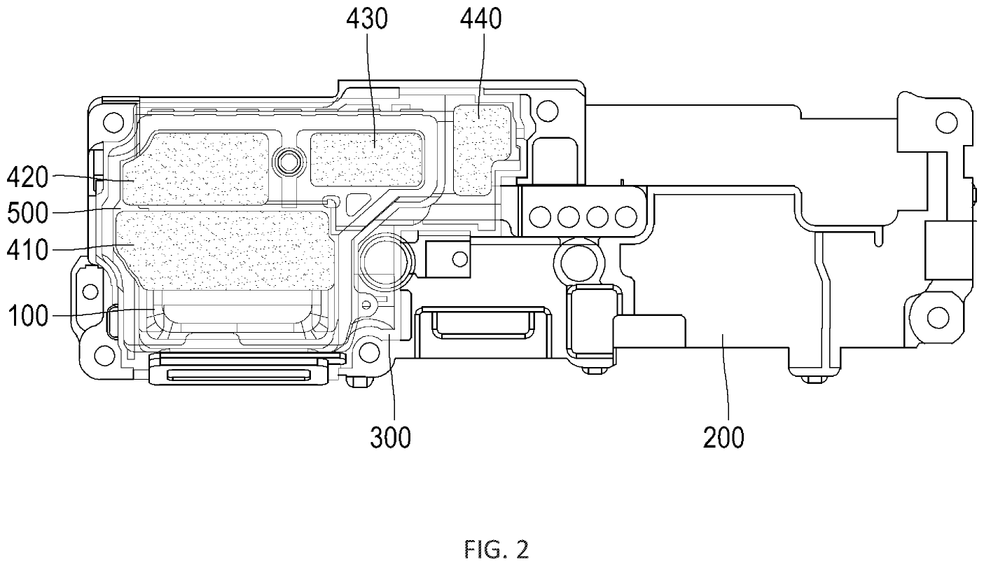

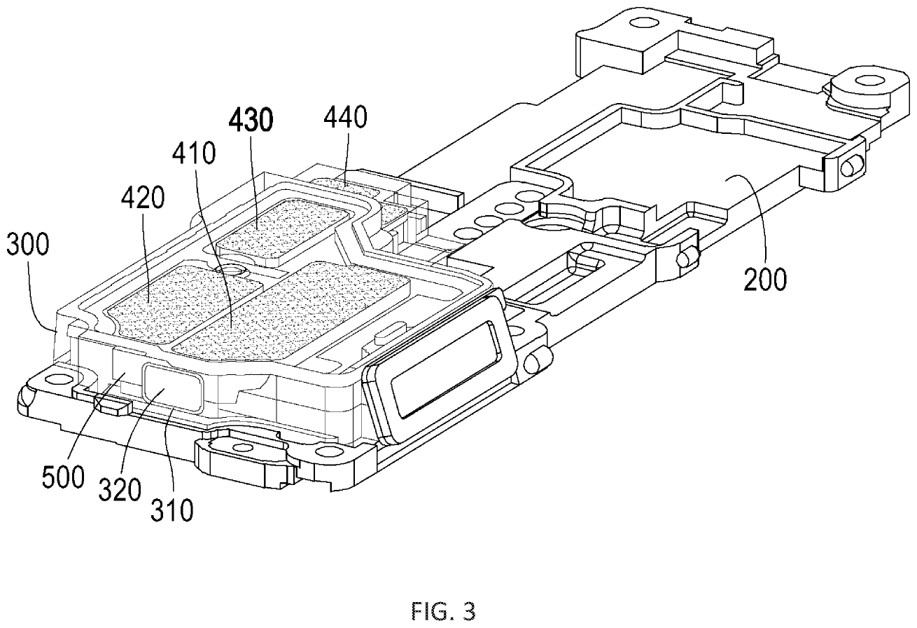

FIG. 2 is a plan view of a microspeaker enclosure including a porous material according to one embodiment of the present disclosure, and FIG. 3 is a perspective view of the microspeaker enclosure including a porous material according to one embodiment of the present disclosure.

The microspeaker enclosure including a block formed of a porous material according to the first embodiment of the present disclosure includes a microspeaker 100, enclosure cases 200 and 300, porous blocks 410, 420, 430 and 440, and porous particles 500. The enclosure cases 200 and 300 may include a lower enclosure case 200 and an upper enclosure case 300, respectively, which are combined to form a back volume therein. The lower enclosure case 200 includes a microspeaker accommodating portion so that the microspeaker 100 may be mounted therein. A backhole (not shown) of the microspeaker 100 communicates with a back volume through the microspeaker accommodating portion.

The porous blocks 410, 420, 430, and 440 may be formed by blocking porous particles and then installed in the back volume, and the porous particles 500 are present in the back volume in a state of unblocked particles. The porous blocks 410, 420, 430, and 440 may be prepared by mixing porous particles having excellent adsorption capability for nitrogen or oxygen occupying most of the air, and then blocking the same.

Here, the porous particles forming the porous blocks 410, 420, 430, and 440 are preferably mixed at a mass ratio of silicon to aluminum in a range of 150:1 to 400:1. The porous particles are excellent in adsorbing not only air but also moisture in the air. Therefore, when moisture is adsorbed on the porous particles, the air adsorption performance may be lowered. Here, when the porous particles are mixed at the mass ratio of silicon to aluminum by 150:1 to 400:1, hydrophobicity of the porous blocks 410, 420, 430, and 440 may be improved, and accordingly, the air adsorption performance may be improved.

Meanwhile, the porous material constituting the porous blocks 410, 420, 430, and 440 and the porous particles 500 may include any one or more of zeolite, activated carbon, a metal-organic framework (MOF), an aerogel, and porous silica. The porous particles 500 used to improve acoustic properties by functioning as a virtual back volume are mainly formed of zeolite and have air adsorption properties that improve acoustic performance up to 300 μm to 500 μm in diameter of zeolite grains. However, even if manufactured in the same component ratio, if the diameter of the zeolite grains is more than 500 μm, the air adsorption properties that improve acoustic performance start to deteriorate. The reason why the properties of improving acoustic performance decrease depending on the size of particles is because air circulation should be made to the inside of most of the filled porous particles according to an operating speed of the microspeake, but the diameter of the zeolite grains exceeding 500 μm may make air circulation difficult and the air adsorption performance of the porous particles gradually decreases. For example, when a block of 1 cm³ is formed of zeolite, the blocked zeolite has no ability to improve acoustic properties.

In addition, a material having adhesiveness, that is, a binder, may be added to the porous blocks 410, 420, 430, and 440 to form a block by combining porous particles with each other. The shape of the porous blocks 410, 420, 430, and 440 are not limited, and may have various shapes, such as a polyhedron or a shape corresponding to the back volume 500.

When the porous blocks 410, 420, 430, and 440 are manufactured to fit the shape of the back volume formed inside the enclosure cases 200 and 300, air circulation is difficult and the size of the block increases, making handling difficult. However, when the porous blocks 410, 420, 430, and 440 are separately manufactured as a plurality of small blocks to be installed, better air circulation may be achieved.

In addition, the porous blocks 410, 420, 430, and 440 may be manufactured to have a thin thickness and may be advantageously manufactured to have a uniform thickness to be arranged, whereas if a width of a space in which the porous blocks 410, 420, 430, and 440 are to be arranged is narrow, the porous blocks 410, 420, 430, and 440 may be easily damaged and difficult to attach.

Here, a space in which the porous blocks 410, 420, 430, and 440 are difficult to attach may be filled with the porous particles 500, thereby applying a porous material even to the space having a narrow width. Meanwhile, a minimum size of the porous particles 500 is very small and a size distribution of the porous particles 500 is large, so that if a thickness of a space to be filled with the porous particles 500 is narrow, the porous particles 500 cannot be uniformly arranged.

In the case of arranging the porous blocks 410, 420, 430, and 440 and the porous particles 500 together as in the present disclosure, the porous particles 500 may be applied to positions in which it is difficult to apply the porous blocks 410, 420, 430, and 440 and the porous blocks 410, 420, 430, and 440 may be applied to positions in which it is difficult to apply the porous particles 500.

The porous particles 500 are injected through a porous particle inlet 310 formed in the upper enclosure case 300. After injecting the porous particles 500, the porous particle inlet 310 is closed by a stopper 320. Meanwhile, the upper enclosure case 300 includes a sound emission hole 330 emitting sound generated by the microspeaker 100. A mesh is mounted on the sound emission hole 330 to prevent external foreign matter from flowing into the enclosure cases 200 and 300 or prevent the porous particles 500 from flowing out of the enclosure cases 200 and 300.

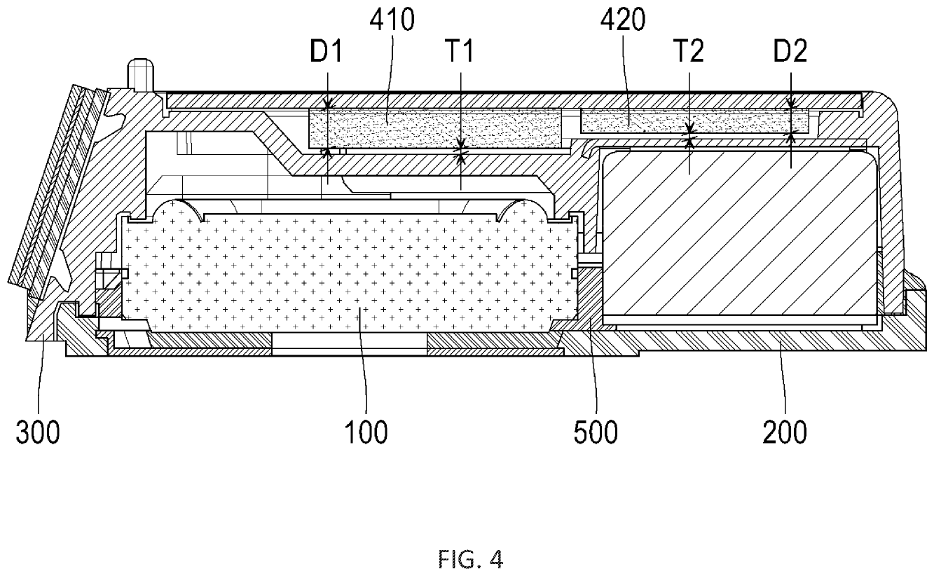

FIG. 4 is a cross-sectional view illustrating a block formed of a porous material according to one embodiment of the present disclosure.

The porous blocks 410, 420, 430, and 440 (refer to FIG. 2) may be attached to one surface of the enclosure case 300, and intervals T1 and T2 between a counterpart facing the porous blocks 410, 420, 430, and 440 and the porous blocks 410, 420, 430, and 440 may be 0.05 mm or more. Here, the counterpart facing the porous blocks 410, 420, 430, and 440 may be at least any one of the enclosure cases 200 and 300, the other porous blocks 410, 420, 430, and 440, the microspeaker 100, a flexible printed circuit board (FPCB), a polyurethane such as PORON, a sound absorbing material, and an electronic component mounted in the enclosure cases 200 and 300.

Meanwhile, each of the porous blocks 410, 420, 430, and 440 may have different thicknesses D1 and D2. The porous blocks 410, 420, 430, and 440 may be installed in installation spaces having different depths within the enclosure cases 200 and 300, respectively, and the porous blocks 410, 420, 430, and 440 may have different thicknesses D1 and D2) according to depths in the installation spaces.

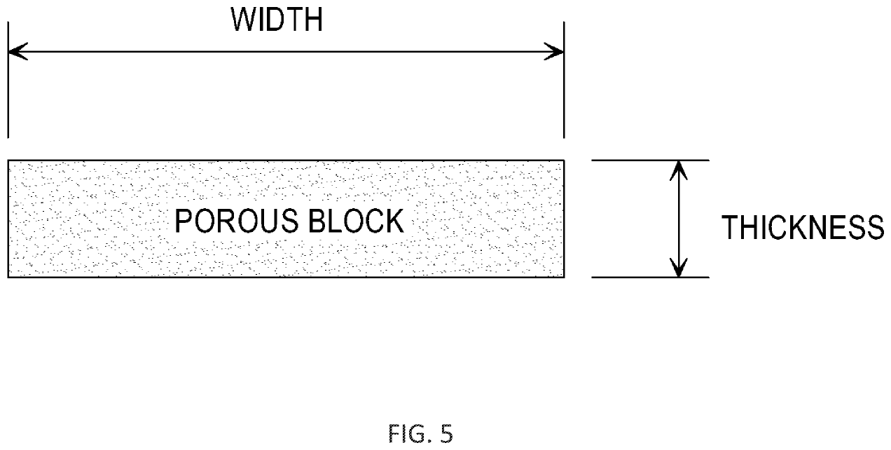

FIG. 5 is a cross-sectional view illustrating a block formed of a porous material according to one embodiment of the present disclosure.

The block formed of a porous material according to the third embodiment of the present disclosure is characterized in that the thickness is limited to improve air adsorption performance and improve air circulation. The porous block preferably has dimensions of 1.5 or more times the width and length compared to the thickness.

As used herein, the terms “having,” “containing,” “including,” “comprising,” and the like are open-ended terms that indicate the presence of stated elements or features, but do not preclude additional elements or features. The articles “a,” “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A microspeaker enclosure, comprising:
a microspeaker;
an enclosure case in which the microspeaker is mounted, including a back volume communicating with the microspeaker;
a block installed in the back volume and formed of a porous material serving as a virtual back volume by adsorbing air; and
porous particles installed in the back volume and serving as a virtual back volume by adsorbing air.

2. The microspeaker enclosure of claim 1, wherein a plurality of blocks formed of a porous material are provided, and the plurality of blocks have different thicknesses.

3. The microspeaker enclosure of claim 1, wherein the block formed of the porous material is attached to one surface of the enclosure case, and wherein an interval between a counterpart that faces the block formed of the porous material and the block formed of the porous material is 0.05 mm or more.

4. The microspeaker enclosure of claim 3, wherein the counterpart that faces the block formed of the porous material is the enclosure case.

5. The microspeaker enclosure of claim 3, wherein the counterpart that faces the block formed of the porous material is another block formed of porous material.

6. The microspeaker enclosure of claim 3, wherein the counterpart that faces the block formed of the porous material is the microspeaker.

7. The microspeaker enclosure of claim 3, wherein the counterpart that faces the block formed of the porous material is a flexible printed circuit board (FPCB).

8. The microspeaker enclosure of claim 3, wherein the counterpart that faces the block formed of the porous material is a polyurethane.

9. The microspeaker enclosure of claim 3, wherein the counterpart that faces the block formed of the porous material is a sound absorbing material.

10. The microspeaker enclosure of claim 3, wherein the counterpart that faces the block formed of the porous material is an electronic component mounted in the enclosure case.

11. The microspeaker enclosure of claim 1, wherein the block formed of the porous material has dimensions in which a width and length of the block formed of the porous material are at least 1.5 times or more a thickness of the block formed of the porous material.

12. The microspeaker enclosure of claim 1, wherein the porous material and the porous particles comprise any one or more of zeolite, activated carbon, a metal-organic framework (MOF), an aerogel, and porous silica.
